(19) United States
(12) Patent Application Publication
(10) Pub. No.: US 2020/0083386 A1
(43) Pub. Date: Mar. 12, 2020

(54) THIN-FILM TRANSISTOR SUBSTRATE, LIQUID CRYSTAL DISPLAY DEVICE, AND ORGANIC ELECTROLUMINESCENT DISPLAY DEVICE

(71) Applicant: Sharp Kabushiki Kaisha, Sakai City (JP)

(72) Inventor: Masahiro YOSHIDA, Sakai City (JP)

(21) Appl. No.: 16/565,591

(22) Filed: Sep. 10, 2019

Related U.S. Application Data
(60) Provisional application No. 62/729,469, filed on Sep. 11, 2018.

(51) Int. Cl. H01L 29/786; H01L 27/12; G02F 1/1333; G02F 1/1362; G02F 1/1368

(52) U.S. Cl. CPC H01L 29/78633; H01L 27/1225; G02F 1/133345; G02F 2201/123; G02F 1/136227; G02F 1/136286; G02F 1/1368; G02F 1/136209

(57) ABSTRACT

The thin-film transistor substrate of the present invention includes: an insulating substrate; and a thin-film transistor disposed on the insulating substrate, the thin-film transistor substrate including, on the insulating substrate, a stack sequentially including a first conductive line layer, a first insulating film, a semiconductor layer, a second insulating film, a second conductive line layer, a third insulating film, and a third conductive line layer, the thin-film transistor including a lower layer gate electrode in the first conductive line layer, the semiconductor layer, an upper layer gate electrode in the second conductive line layer, and a switching electrode in the third conductive line layer, the lower layer gate electrode and the upper layer gate electrode being connected to each other via the switching electrode.

### CROSS-REFERENCE TO RELATED APPLICATIONS

The present application claims priority under 35 U.S.C. § 119 to U.S. Provisional Patent Application No. 62/729,469 filed on Sep. 11, 2018, the contents of which are incorporated herein by reference in their entirety.

### BACKGROUND OF THE INVENTION

### Field of the Invention

The present invention relates to thin-film transistor substrates, liquid crystal display devices, and organic electroluminescent display devices. More specifically, the present invention relates to a thin-film transistor substrate with thin-film transistors each including a lower layer gate electrode and an upper layer gate electrode, and a liquid crystal display device and an organic electroluminescent display device each including the thin-film transistor substrate.

### Description of Related Art

Thin display devices such as liquid crystal display devices and organic electroluminescent (hereinafter, also abbreviated to EL) display devices typically include a thin-film transistor substrate including many thin-film transistors (hereinafter, also abbreviated to TFTs). Known TFTs include single gate TFTs each including one gate electrode and double gate TFTs each including two gate electrodes, one in an upper layer relative to a semiconductor layer and the other in a lower layer relative to the semiconductor layer. A conventional semiconductor layer of a TFT is made of a silicon material such as amorphous silicon or polycrystalline silicon, while a recent semiconductor layer is sometimes made of an oxide semiconductor.

Oxide semiconductors have advantages such as high electrical mobility and a comparatively simple film formation process. Yet, an oxide semiconductor layer in a top gate TFT, a kind of single gate TFT, may lower the performance of the TFT as it is irradiated with light from the backlight of the liquid crystal display device.

WO 2015/186619 and JP 2013-251526 A each disclose a top gate TFT including an oxide semiconductor layer and a light-shielding film in a lower layer relative to the oxide semiconductor layer.

JP 2013-251526 A also discloses a double gate TFT including an oxide semiconductor layer.

### BRIEF SUMMARY OF THE INVENTION

A top gate TFT including an oxide semiconductor layer requires more photolithography steps (the number of photomasks) in the case where its channel light-shielding film is used also as a lower layer gate electrode (in the case where the TFT has a double gate structure in which gate electrodes are formed, one in an upper layer relative to the semiconductor layer and the other in a lower layer relative to the semiconductor layer).

Specifically, in order to connect the upper layer gate electrode connected to a gate line and the lower layer gate electrode formed using a channel light-shielding film, a specialized step (photomask) is required to form a contact hole in a lower layer insulating film between the upper layer gate electrode and the lower layer gate electrode.

This step is further described with reference to FIG. 12 to FIG. 15. FIG. 12 is a schematic plan view of a liquid crystal display device of Comparative Embodiment 1. A liquid crystal display device 100R of Comparative Embodiment 1 includes a thin-film transistor substrate (hereinafter, TFT substrate) 100AR, a counter substrate 100BR facing the TFT substrate 100AR, and a liquid crystal layer (not shown) between the TFT substrate 100AR and the counter substrate 100BR.

The TFT substrate 100AR includes data lines 101R, gate lines 102R intersecting the data lines 101R, and thin-film transistors (hereinafter, TFTs) 103R serving as switching elements. In each region surrounded by two adjacent data lines 101R and two adjacent gate lines 102R is disposed a pixel electrode 118R. Each pixel electrode 118R is connected to the corresponding data line 101R via the semiconductor layer of the corresponding TFT 103R. A common electrode 120R provided with slits (openings) 120SR is formed above the pixel electrodes 118R to cover substantially the entire display region except for the slits 120SR. The counter substrate 100BR includes a color filter layer (not shown) and a black matrix layer 121R.

FIG. 13 is an enlarged schematic plan view of the region surrounded by the dashed line in FIG. 12. FIG. 14 and FIG. 15 are schematic cross-sectional views of a TFT substrate in the liquid crystal display device of Comparative Embodiment 1. FIG. 14 and FIG. 15 show cross sections taken along the line D1-D2 and the line E1-E2 in FIG. 13, respectively.

The TFT substrate 100AR includes, on an insulating substrate 110R, a stack sequentially including a first conductive line layer 111R, a lower layer insulating film 112R as a first insulating film, a semiconductor layer 113R, a gate insulating film 114R as a second insulating film, a second conductive line layer 115R, a first protective film 116R (a stack of an inorganic insulating film 116AR and a photosensitive organic film 116BR) as a third insulating film, a third conductive line layer 117R, the pixel electrodes 118R, a second protective film 119R as a fourth insulating film, and the common electrode 120R. The first conductive line layer 111R includes the data lines 101R and lower layer gate electrodes 103G1R. The second conductive line layer 115R includes the gate lines 102R and upper layer gate electrodes 103G2R. The third conductive line layer 117R includes conductive lines 120AR and connection electrodes 117CR. The conductive lines 120AR can be used to control the resistance distribution of the common electrode 120R within the display region. Each pixel electrode 118R is connected to the corresponding drain region of the semiconductor layer 113R via the corresponding connection electrode 117CR. Each TFT 103R in Comparative Embodiment 1 is a double gate TFT including the semiconductor layer 113R between its lower layer gate electrode 103G1R and its upper layer gate electrode 103G2R.

As shown in FIG. 14, in the liquid crystal display device 100R of Comparative Embodiment 1, the lower layer gate electrode 103G1R and the upper layer gate electrode 103G2R are directly connected to each other in the corresponding contact hole 100CH1R formed in the lower layer insulating film 112R and the gate insulating film 114R. This structure requires a specialized photolithography step (photomask) to form the contact hole 100CH1R in each of the lower layer insulating film 112R and the gate insulating film 114R.

As shown in FIG. 15, in the liquid crystal display device 100R of Comparative Embodiment 1, the data lines 101R are formed in the same layer as the lower layer gate electrodes 103G1R. This structure requires a contact hole 100CH2R to connect the source region of each TFT 103R to the corresponding data line 101R. The specialized photolithography step (photomask) to form the contact holes 100CH1R in the lower layer insulating film 112R is necessary to form these contact holes 100CH2R as well.

JP 2013-251526 A discloses in FIG. 9 and FIG. 10 a structure in which an upper gate electrode in the third conductive layer as with the pixel electrodes is connected to the corresponding gate electrode formed in the first conductive layer. The upper gate electrode and the gate electrode are directly connected to each other through a contact hole. Thus, in the case of forming the upper gate electrode in the second conductive layer and connecting the upper gate electrode to the gate electrode as in Comparative Embodiment 1, a specialized photolithography step (photomask) is required to form a contact hole in the gate insulating film between the first and second conductive layers.

JP 2013-251526 A also discloses in FIG. 20 a structure in which a data line formed in the same layer as the light-shielding film and the corresponding source region are connected via the corresponding source electrode. JP 2013-251526 A, however, does not clearly show application of this structure to a structure using a channel light-shielding film as gate electrodes (lower layer gate electrodes).

The present invention was made in view of the current state of the art, and an object of the present invention is to provide a thin-film transistor substrate which includes thin-film transistors each including an upper layer gate electrode and a lower layer gate electrode and with which the number of photomasks used in the production process can be reduced; a liquid crystal display device; and an organic electroluminescent display device.

(1) An aspect of the present invention is directed to a thin-film transistor substrate including: an insulating substrate; and a thin-film transistor disposed on the insulating substrate, the thin-film transistor substrate including, on the insulating substrate, a stack sequentially including a first conductive line layer, a first insulating film, a semiconductor layer, a second insulating film, a second conductive line layer, a third insulating film, and a third conductive line layer, the thin-film transistor including a lower layer gate electrode in the first conductive line layer, the semiconductor layer, an upper layer gate electrode in the second conductive line layer, and a switching electrode in the third conductive line layer, the lower layer gate electrode and the upper layer gate electrode being connected to each other via the switching electrode.

(2) In an embodiment of the present invention, the thin-film transistor substrate includes the structure (1), and the lower layer gate electrode and the upper layer gate electrode are connected to each other via the switching electrode at both sides of the semiconductor layer.

(3) In an embodiment of the present invention, the thin-film transistor substrate includes the structure (1) or (2), and the switching electrode includes a first switching electrode and a second switching electrode, the lower layer gate electrode and the upper layer gate electrode are connected to each other via the first switching electrode at one side of the semiconductor layer, and the lower layer gate electrode and the upper layer gate electrode are connected to each other via the second switching electrode at the other side of the semiconductor layer.

(4) In an embodiment of the present invention, the thin-film transistor substrate includes the structure (1), (2), or (3), and further includes at least one of a conductive line or an electrode in the third conductive line layer.

(5) Another aspect of the present invention is directed to a liquid crystal display device including the thin-film transistor substrate including the structure (1), (2), (3), or (4).

(6) Yet another aspect of the present invention is directed to an organic electroluminescent display device including the thin-film transistor substrate including the structure (1), (2), (3), or (4).

The present invention can provide a thin-film transistor substrate which includes thin-film transistors each including an upper layer gate electrode and a lower layer gate electrode and with which the number of photomasks used in the production process can be reduced; a liquid crystal display device; and an organic electroluminescent display device.

### BRIEF DESCRIPTION OF THE DRAWINGS

FIG. 1 is a schematic plan view of a liquid crystal display device of Embodiment 1.

FIG. 2 is an enlarged schematic plan view of the region surrounded by the dashed line in FIG. 1.

FIG. 3 is a schematic cross-sectional view of a TFT substrate in the liquid crystal display device of Embodiment 1.

FIG. 4A is another schematic cross-sectional view of the TFT substrate in the liquid crystal display device of Embodiment 1.

FIG. 4B is yet another schematic cross-sectional view of the TFT substrate in the liquid crystal display device of Embodiment 1.

FIG. 5 is a view showing the production process of the TFT substrate in the liquid crystal display device of Embodiment 1.

FIG. 6 is a schematic plan view of a liquid crystal display device of Embodiment 2.

FIG. 7 is a schematic plan view of a liquid crystal display device of Embodiment 3.

FIG. 8 is a schematic plan view of an organic electroluminescent display device of Embodiment 4.

FIG. 9 is a schematic plan view of the organic electroluminescent display device of Embodiment 4, with a first conductive line layer and a second conductive line layer highlighted.

FIG. 10 is a schematic plan view of the organic electroluminescent display device of Embodiment 4, with a third conductive line layer highlighted.

FIG. 11 is a schematic cross-sectional view of the organic electroluminescent display device of Embodiment 4.

FIG. 12 is a schematic plan view of a liquid crystal display device of Comparative Embodiment 1.

FIG. 13 is an enlarged schematic plan view of the region surrounded by the dashed line in FIG. 12.

FIG. 14 is a schematic cross-sectional view of a TFT substrate in the liquid crystal display device of Comparative Embodiment 1.

FIG. 15 is a schematic cross-sectional view of the TFT substrate in the liquid crystal display device of Comparative Embodiment 1.

FIG. 16 is a view showing the production process of the TFT substrate in the liquid crystal display device of Comparative Embodiment 1.

### DETAILED DESCRIPTION OF THE INVENTION

Hereinafter, thin-film transistor substrates, liquid crystal display devices, and organic electroluminescent display devices of embodiments of the present invention are described. The embodiments are not intended to limit the scope of the present invention. The design may be modified as appropriate within the range satisfying the configuration of the present invention. The configurations in the embodiments may appropriately be combined or modified within the spirit of the present invention.

The thin-film transistor substrates (hereinafter, TFT substrates) of the embodiments of the present invention each include an insulating substrate and thin-film transistors (hereinafter, TFTs) disposed on the insulating substrate. The TFT substrate includes, on the insulating substrate, a stack sequentially including a first conductive line layer, a first insulating film, a semiconductor layer, a second insulating film, a second conductive line layer, a third insulating film, and a third conductive line layer. The thin-film transistors each include a lower layer gate electrode in the first conductive line layer, the semiconductor layer, an upper layer gate electrode in the second conductive line layer, and a switching electrode in the third conductive line layer. The lower layer gate electrode and the upper layer gate electrode are connected to each other via the switching electrode.

In the TFT substrate, the lower layer gate electrode is disposed in the first conductive line layer, which is the first conductive layer, and the upper layer gate electrode is disposed in the second conductive line layer, which is the second conductive layer. The lower layer gate electrode and the upper layer gate electrode are connected to each other via the switching electrode in the third conductive line layer on the third insulating film. Thus, contact holes can be formed in the first insulating film using the photomask used to pattern the third insulating film. In other words, a specialized photomask to form contact holes in the first insulating film is not necessary, so that the number of photomasks used in the production process can be reduced.

The third insulating film is therefore preferably a patterned insulating film, and is preferably an insulating film provided with openings.

Here, a first opening from which at least the first insulating film and the third insulating film are removed may be formed on the lower layer gate electrode, and thereby the lower layer gate electrode and the switching electrode may be connected to each other within the first opening.

Also, a second opening from which at least the third insulating film is removed may be formed on the upper layer gate electrode, and thereby the upper layer gate electrode and the switching electrode may be connected to each other within the second opening.

The upper layer gate electrode and the lower layer gate electrode are each a gate electrode. The “gate electrode” is one of the three electrodes constituting a TFT (the other electrodes are a source electrode and a drain electrode), and modulates the charge amount to be induced in the corresponding channel region of the semiconductor layer according to the voltage applied to the gate electrode (e.g., the scanning signal supplied from a gate line), thereby controlling the current flowing between the source and drain electrodes. The first conductive line layer in which the lower layer gate electrode is disposed is positioned on the lower side of the semiconductor layer, and the second conductive line layer in which the upper layer gate electrode is disposed is positioned on the upper side of the semiconductor layer.

The “semiconductor layer” includes layers having the characteristics of semiconductors (e.g., channel regions) and layers (e.g., source regions and drain regions) having been subjected to a resistance reduction treatment (hereinafter, also referred to as conduction imparting treatment) causing a layer having the characteristics of semiconductors to have a lower resistivity than the channel regions.

The “gate line” is a line connected to gate electrodes (typically, a bus line connected to gate electrodes) of TFTs and supplies a scanning signal (signal that controls the on and off states of a TFT) to the gate electrodes of the TFTs connected. A “data line” is a line connected to source electrodes (typically, a bus line connected to source electrodes) of TFTs and supplies a data signal (e.g., video signal) to the TFTs connected.

Typically, one of the gate line and the data line is disposed linearly to vertically cross the array region in which the TFTs are arranged in a matrix, and the other is disposed linearly to horizontally cross the array region. At least one of the lower layer data line or the upper layer data line is typically disposed linearly to horizontally or vertically cross the array region.

Each of the conductive line layers and the insulating films may be a single layer formed from a signal material, or may be a stack of layers of which adjacent two layers are formed from different materials.

Each conductive line layer may be formed from any material, but is preferably formed from a metal. Each conductive line layer is preferably a metal layer.

The lower layer gate electrode and the upper layer gate electrode are preferably connected to each other via the switching electrode at both sides of the semiconductor layer (each channel width direction side of the semiconductor layer). This structure can reduce the resistance of the gate line connected to the lower layer gate electrode and the upper layer gate electrode and increase the redundancy of the gate line. From the same viewpoint, the lower layer gate electrode and the upper layer gate electrode may be connected to the switching electrode at both sides of the semiconductor layer.

From the viewpoints of resistance reduction for the gate line and redundancy increase for the gate line, preferably, the switching electrode includes first and second switching electrodes, the lower layer gate electrode and the upper layer gate electrode are connected to each other via the first switching electrode at one side of the semiconductor layer (one channel width direction side of the semiconductor layer), and the lower layer gate electrode and the upper layer gate electrode are connected to each other via the second switching electrode at the other side of the semiconductor layer (the other channel width direction side of the semiconductor layer). This structure can reduce the area occupied by the switching electrodes as compared with a structure in which one switching electrode is disposed to cover the semiconductor layer described above. Since the switching electrodes are closer to the common electrode than the lower layer gate electrode and the upper layer gate electrode are, reduction in area of the switching electrodes enables reduction in capacitance of the switching electrodes, i.e., capacitance between the gate lines connected to the switching electrodes and the common electrode, thereby reducing signal dullness of the gate lines.

The TFT substrate preferably further includes at least one of a conductive line or an electrode in the third conductive line layer. This enables effective use of the third conductive line layer as a component other than the switching electrode.

The conductive line in the third conductive line layer may function as any component. Specific suitable examples of the component include a conductive line to reduce the resistance variation of the common electrode in the case where the TFT substrate is used in a liquid crystal display device; a touch panel line (TP line) in the case where the TFT substrate is used in a liquid crystal display device including an in-cell touch panel; and an initialization power line or an anode side power line in the case where the TFT substrate is used in an organic EL display device.

The electrode in the third conductive line layer may function as any component. Specific suitable examples of the component include a switching electrode that connects a source region of the semiconductor layer and the data line in the first conductive line layer.

The liquid crystal display devices of the embodiments of the present invention each include the TFT substrate.

The organic EL display devices (OLEDs) of the embodiments of the present invention each include the TFT substrate.

Hereinafter, the thin-film transistor substrates, the liquid crystal display devices, and the organic electroluminescent display devices of other embodiments of the present invention are described in more detail with reference to the drawings. In the following description, members having the same or similar functions in different drawings are commonly provided with the same reference sign so as to avoid repetition of description.

### Embodiment 1

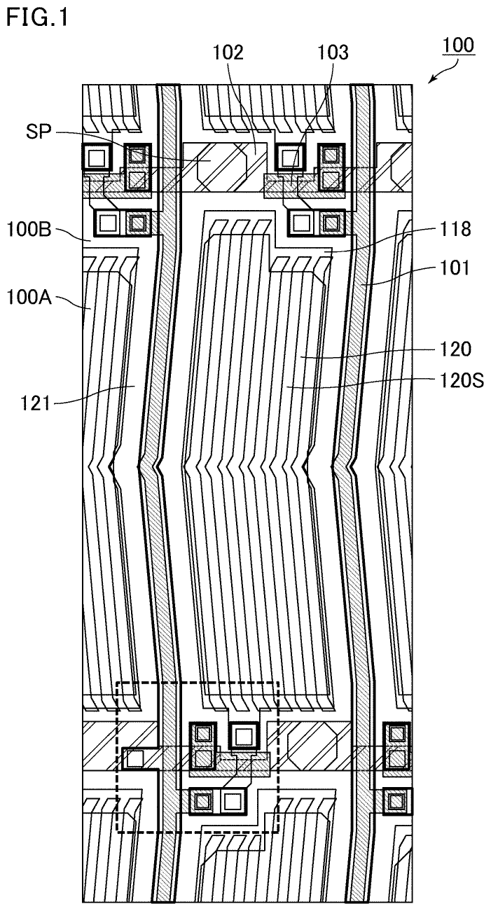

FIG. 1 is a schematic plan view of a liquid crystal display device of Embodiment 1. FIG. 1 shows the third conductive line layer with thick lines. As shown in FIG. 1, a liquid crystal display device 100 of the present embodiment includes a thin-film transistor substrate (hereinafter, TFT substrate) 100A, a counter substrate 100B facing the TFT substrate 100A, and a liquid crystal layer (not shown) between the TFT substrate 100A and the counter substrate 100B. The TFT substrate 100A in the present embodiment is also referred to as an array substrate.

The liquid crystal display device 100 includes a first alignment film (not shown) between the TFT substrate 100A and the liquid crystal layer; a second alignment film (not shown) between the counter substrate 100B and the liquid crystal layer; a first polarizing plate (not shown) on the surface remote from the liquid crystal layer of the TFT substrate 100A; a second polarizing plate (not shown) on the surface remote from the liquid crystal layer of the counter substrate 100B; and a backlight (not shown) on the surface remote from the liquid crystal layer of the first polarizing plate. The first polarizing plate and the second polarizing plate are in crossed Nicols in which their polarization axes are perpendicular to each other.

The TFT substrate 100A includes data lines 101, gate lines 102 intersecting the data lines 101, and thin-film transistors (hereinafter, TFTs) 103 serving as switching elements. In each region surrounded by two adjacent data lines 101 and two adjacent gate lines 102 is disposed a pixel electrode 118. Each pixel electrode 118 is connected to the corresponding data line 101 via the semiconductor layer of the corresponding TFT 103. A common electrode 120 provided with slits (openings) 120S is formed on the pixel electrodes 118 with a second protective film (not shown in FIG. 1) serving as a fourth insulating film in between to cover substantially the entire display region except for the slits 120S.

The liquid crystal display device 100 further includes a source driver (not shown) connected to the data lines 101, a gate driver (not shown) connected to the gate lines 102, and a controller (not shown). The gate driver sequentially supplies scanning signals to the gate lines 102 based on the control by the controller. The source driver supplies data signals to the data lines 101 based on the control by the controller when the corresponding TFTs 103 are in the voltage applied state according to the scanning signals. Each pixel electrode 118 is set at a potential according to the data signal supplied thereto through the corresponding TFT 103, so that a fringe electric field is generated between the pixel electrode 118 and the common electrode and thereby the liquid crystal molecules in the liquid crystal layer are rotated. In this manner, the magnitude of voltage applied between each pixel electrode 118 and the common electrode is controlled to change the retardation in the liquid crystal layer, whereby transmission and blocking of light is controlled. The liquid crystal display device 100 of the present embodiment is a fringe field switching (FFS) mode liquid crystal display device. In the present embodiment, a 16.1-inch FHD display (with a dot pitch equivalent to 62 μm×186 μm) is assumed to be in the FFS mode.

The counter substrate 100B includes, sequentially toward the liquid crystal layer, an insulating substrate (not shown), a black matrix layer 121, and a color filter layer (not shown). In the light-shielding region in which the black matrix layer 121 is disposed are provided spacers SP, which maintain the cell gap to the given thickness. The color filter layer includes red color filters, green color filters, and blue color filters, and has a structure in which these color filters are partitioned by the black matrix layer 121.

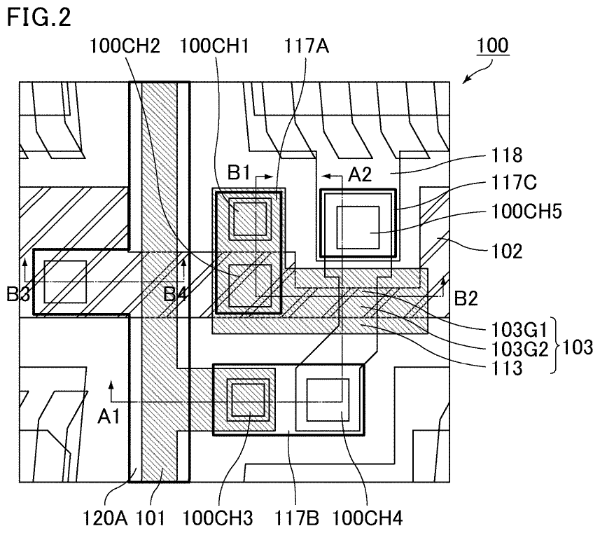

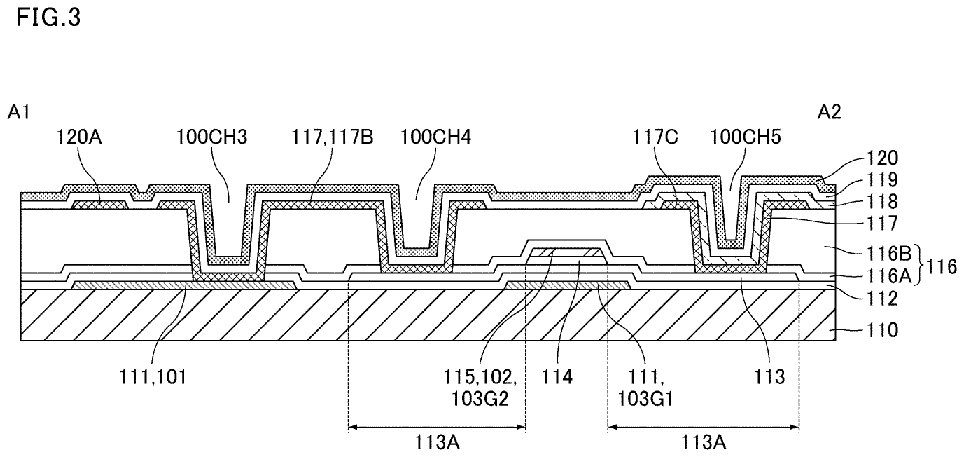

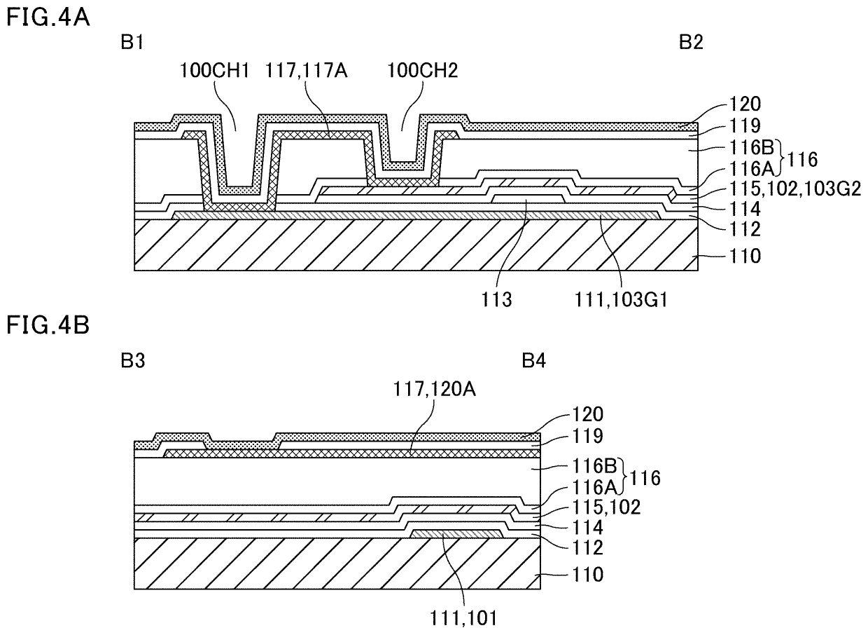

FIG. 2 is an enlarged schematic plan view of the region surrounded by the dashed line in FIG. 1. FIG. 2 shows the third conductive line layer with thick lines. FIG. 3, FIG. 4A, and FIG. 4B are schematic cross-sectional views of a TFT substrate in the liquid crystal display device of Embodiment 1. FIG. 3 shows the cross section taken along the line A1-A2 in FIG. 2. FIG. 4A shows the cross section taken along the line B1-B2 in FIG. 2. FIG. 4B shows the cross section taken along the line B3-B4 in FIG. 2.

The TFT substrate 100A includes, on the insulating substrate 110, a stack sequentially including a first conductive line layer 111, a lower layer insulating film 112 as a first insulating film, a semiconductor layer 113, a gate insulating film 114 as a second insulating film, a second conductive line layer 115, a first protective film 116 as a third insulating film, a third conductive line layer 117, a pixel electrode 118 (first transparent conductive film), a second protective film 119 as a fourth insulating film, and a common electrode 120 (second transparent conductive film). The first conductive line layer 111 includes the data lines 101 and lower layer gate electrodes 103G1. The second conductive line layer 115 includes the gate lines 102 and upper layer gate electrodes 103G2. Each upper layer gate electrode 103G2 is part of the corresponding gate line 102, and thus the gate line 102 and the upper layer gate electrode 103G2 are connected to each other. Each TFT 103 in the present embodiment is a double gate TFT including the semiconductor layer 113 between its lower layer gate electrode 103G1 and upper layer gate electrode 103G2. The lower layer gate electrodes 103G1 function also as a channel light-shielding film. Each TFT 103 is assumed to, but not limited to, have a self-alignment structure in which the gate insulating film 114 is patterned and the semiconductor layer 113 is subjected to the resistance reduction (conduction imparting) treatment in the pattern of the upper layer gate electrodes 103G2.

The conductive line layer including the data lines 101 and the gate lines 102 may be any conductive line layer, and may include, for example, the gate lines 102 in the first conductive line layer 111 and the data lines 101 in the second conductive line layer 115.

Each upper layer gate electrode 103G2 and the corresponding lower layer gate electrode 103G1 are on the upper and lower sides of the semiconductor layer 113, respectively, with an insulating film in between. One of the upper layer gate electrode 103G2 and the lower layer gate electrode 103G1 (e.g., lower layer gate electrode 103G1) overlaps the other (e.g., upper layer gate electrode 103G2) in a region where at least the semiconductor layer 113 is disposed in a plan view.

Each lower layer gate electrode 103G1 and the corresponding upper layer gate electrode 103G2 are connected to each other via a switching electrode 117A in the third conductive line layer 117. As described above, each TFT 103 includes a lower layer gate electrode 103G1 formed on the insulating substrate 110, the semiconductor layer 113 formed in an upper layer relative to the lower layer gate electrode 103G1 with the lower layer insulating film 112 in between, an upper layer gate electrode 103G2 formed in an upper layer relative to the semiconductor layer 113 with the gate insulating film 114 in between, and the first protective film 116 formed in an upper layer relative to the upper layer gate electrode 103G2, wherein the lower layer gate electrode 103G1 and the upper layer gate electrode 103G2 are connected to each other via the third conductive line layer 117 on the first protective film 116.

In the present embodiment, as shown in FIG. 2 and FIG. 4A, the lower layer gate electrode 103G1 and the upper layer gate electrode 103G2 are connected to each other via the switching electrode 117A at one side of the semiconductor layer 113 (one channel width direction side of the semiconductor layer 113).

As shown in FIG. 2 and FIG. 4A, the switching electrode 117A in the third conductive line layer 117 is connected to the lower layer gate electrode 103G1 in the corresponding contact hole 100CH1 as a first opening in the first protective film 116 and the lower layer insulating film 112, and connected to the upper layer gate electrode 103G2 in the corresponding contact hole 100CH2 as a second opening in the first protective film 116. The inner quadrilateral portion in the contact hole 100CH1 shown in FIG. 2 indicates the contact hole in the lower layer insulating film 112, and the outer quadrilateral portion in the contact hole 100CH1 indicates the contact hole in the first protective film 116.

Here, the two contact holes 100CH1 and 100CH2 as shown in FIG. 4A may not be formed, and one contact hole may be formed to overlap both the lower layer gate electrode 103G1 and the upper layer gate electrode 103G2.

In the third conductive line layer 117, as shown in FIG. 4B, for example, a conductive line 120A connected to the common electrode 120 can be formed. This structure can reduce the resistance variation within the display region. The connection portion between the common electrode 120 and the conductive line 120A shown in FIG. 4B is not necessarily formed in every pixel.

In the case where the liquid crystal display device 100 includes an in-cell touch panel, the third conductive line layer 117 can also be used as touch panel lines (TP lines). In this case, the common electrode 120 is divided into quadrilateral electrodes having sides of about 2 mm to 6 mm, for example, and each quadrilateral electrode is connected to at least one TP line such that the common electrode 120 functions as a touch sensor electrode (TP electrode).

As shown in FIG. 2 and FIG. 3, the switching structure via the third conductive line layer 117 is also applicable to a portion connecting the source region of a TFT 103 and the corresponding data line 101 in the same layer as the corresponding lower layer gate electrode 103G1. Specifically, a switching electrode 117B in the third conductive line layer 117 is connected to the corresponding data line 101 in the corresponding contact hole 100CH3 as a third opening in the first protective film 116 and the lower layer insulating film 112, and connected to the corresponding source region of the semiconductor layer 113 in the corresponding contact hole 100CH4 as a fourth opening in the first protective film 116. The inner quadrilateral portion in the contact hole 100CH3 shown in FIG. 2 indicates the contact hole in the lower layer insulating film 112, and the outer quadrilateral portion in the contact hole 100CH3 indicates the contact hole in the first protective film 116.

As shown in FIG. 3, each pixel electrode 118 is connected to the corresponding drain region of the semiconductor layer 113 in the corresponding contact hole 100CH5 as a fifth opening in the first protective film 116. As shown in FIG. 2 and FIG. 3, the pixel electrode 118 may be connected to the corresponding drain region of the semiconductor layer 113 via the corresponding connection electrode 117C in the third conductive line layer 117. Although some production processes may expose the surface of the drain regions of the semiconductor layer 113 to etching without the connection electrodes 117C constituting the pattern of the third conductive line layer 117, the connection electrodes 117C, when disposed, can function as a protective film during etching.

The insulating substrate 110 is a substrate having insulation properties. Examples of the insulating substrate 110 include transparent substrates such as glass substrates and plastic substrates.

The conductive lines and electrodes in the first conductive line layer 111, the second conductive line layer 115, and the third conductive line layer 117 can be formed by forming a single-layer or multi-layer film from a metal such as copper, titanium, aluminum, molybdenum, or tungsten, or an alloy thereof by a method such as sputtering, and then patterning the film by a method such as photolithography.

The semiconductor layer 113 can be formed from an oxide semiconductor, such as an InGaZnO-based oxide semiconductor.

The lower layer insulating film 112, the gate insulating film 114, the first protective film 116, and the second protective film 119 can each be an inorganic insulating film, an organic insulating film, or a stack of an organic insulating film and an inorganic insulating film. The inorganic insulating film can be, for example, an inorganic film such as a silicon nitride (SiNₓ) or silicon oxide (SiO₂) film, or a stack of such films. The organic insulating film can be, for example, a photosensitive organic film such as a photosensitive acrylic resin film.

In the present embodiment, the lower layer insulating film 112, the gate insulating film 114, and the second protective film 119 are each an inorganic insulating film, and the first protective film 116 is a stack of the inorganic insulating film 116A and the photosensitive organic film (organic insulating film) 116B. Specifically, the lower layer insulating film 112 is a SiO₂ layer, the gate insulating film 114 is a SiO₂ layer, the second protective film 119 is a SiNₓ layer, and the first protective film 116 is a stack sequentially including a SiO₂ layer and a photosensitive organic film from the insulating substrate 110 side.

The pixel electrodes 118 and the common electrode 120 can be formed by, for example, forming a single-layer or multiple-layer film from a transparent conductive material such as indium tin oxide (ITO), indium zinc oxide (IZO), zinc oxide (ZnO), or tin oxide (SnO), or an alloy thereof by a method such as sputtering, and then patterning the film by photolithography.

In the present embodiment, each lower layer gate electrode 103G1 and the corresponding upper layer gate electrode 103G2 are not directly connected to each other, but are connected to each other via the third conductive line layer 117 on the first protective film 116. This structure eliminates a specialized step (photomask) to form contact holes in the lower layer insulating film 112. The following describes the details of the process.

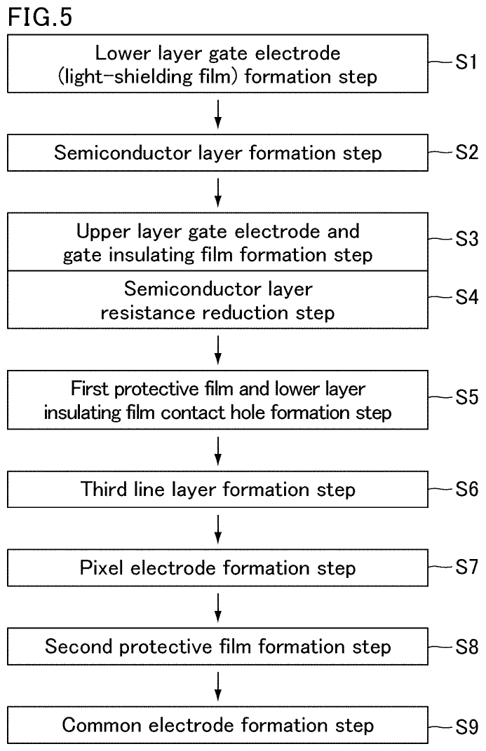

FIG. 5 is a view showing the production process of the TFT substrate in the liquid crystal display device of Embodiment 1. The production process of the liquid crystal display device 1 of the present embodiment is described with reference to FIG. 5.

In a lower layer gate electrode (light-shielding film) formation step S1, a first conductive film is formed on an insulating substrate by sputtering, and a resist pattern is formed by photolithography using a photomask. The first conductive film is patterned by etching using the resist pattern as a mask. The resist pattern is then removed, so that the first conductive line layer 111 including the lower layer gate electrodes 103G1 (light-shielding film) is formed.

In a semiconductor layer formation step S2, the lower layer insulating film 112 is formed on the first conductive line layer 111 by chemical vapor deposition (CVD), a semiconductor film is formed by sputtering, and a resist pattern is formed by photolithography using a photomask. The semiconductor film is patterned by etching using the resist pattern as a mask. The resist pattern is then removed, so that the lower layer insulating film 112 and the semiconductor layer 113 are formed.

In an upper layer gate electrode and gate insulating film formation step S3, the gate insulating film 114 is formed on the semiconductor layer 113 by CVD, a second conductive film is formed by sputtering, and a resist pattern is formed by photolithography using a photomask. The second conductive film is patterned by etching using the resist pattern as a mask, so that the second conductive line layer 115 including the upper layer gate electrodes 103G2 is formed. The gate insulating film 114 is patterned by etching also using the above resist pattern, followed by removal of the resist pattern. In this manner, in the production process employed in the present embodiment, formation of the second conductive line layer 115 and patterning of the gate insulating film 114 can be performed in the same step. Also in the present embodiment, the second conductive line layer 115 including the upper layer gate electrodes 103G2 and the gate insulating film 114 are formed to have substantially the same planar shape.

In a semiconductor layer resistance reduction step S4, the semiconductor layer 113 is subjected to the resistance reduction treatment using the upper layer gate electrodes 103G2 and the gate insulating film 114 overlapping the upper layer gate electrodes 103G2 as masks so as to form conduction imparted portions 113A (source regions and drain regions). The semiconductor layer 113 except for the conduction imparted portions 113A functions as a channel region.

In a first protective film and lower layer insulating film contact hole formation step S5, the inorganic insulating film 116A is formed on the second conductive line layer 115 by CVD. A photosensitive organic film material is applied to the inorganic insulating film 116A by spin coating or slit coating, and the material is patterned by photolithography using a photomask, so that the photosensitive organic film 116B is formed. The inorganic insulating film 116A is etched in the pattern of the photosensitive organic film 116B to form contact holes in the inorganic insulating film 116A, and then the lower layer insulating film 112 is etched also in the pattern of the photosensitive organic film 116B to form contact holes in the lower layer insulating film 112. In this manner, in the production process employed in the present embodiment, formation of contact holes in the inorganic insulating film 116A and formation of contact holes in the lower layer insulating film 112 can be performed in the same step. This step forms the contact holes 100CH1 shown in the figures including FIG. 2, and connects the lower layer gate electrodes 103G1 and the respective upper layer gate electrodes 103G2 via the third conductive line layer 117.

In a third conductive line layer formation step S6, a third conductive film is formed on the photosensitive organic film 116B by sputtering, and a resist pattern is formed by photolithography using a photomask. The third conductive film is patterned by etching using the resist pattern as a mask. The resist pattern is then removed, so that the third conductive line layer 117 is formed.

In a pixel electrode formation step S7, a first transparent conductive film is formed on the third conductive line layer 117 by sputtering, and a resist pattern is formed by photolithography using a photomask. The first transparent conductive film is patterned by etching using the resist pattern as a mask. The resist pattern is then removed, so that the pixel electrodes 118 are formed.

In a second protective film formation step S8, the second protective film 119 is formed on the pixel electrodes 118 by CVD, and a resist pattern is formed by photolithography using a photomask. The second protective film 119 is patterned by etching using the resist pattern as a mask, so that contact holes are formed in the second protective film 119.

In a common electrode formation step S9, a second transparent conductive film is formed on the second protective film 119 by sputtering, and a resist pattern is formed by photolithography using a photomask. The second transparent conductive film is patterned by etching using the resist pattern as a mask. The resist pattern is then removed, so that the common electrode 120 is formed.

In the production process of the liquid crystal display device 1 of the present embodiment, as described for the upper layer gate electrode and gate insulating film formation step S3 in FIG. 5, the gate insulating film 114 can be patterned in the same step as the step of forming the second conductive line layer 115. Also, as described for the first protective film and lower layer insulating film contact hole formation step S5 in FIG. 5, after formation of contact holes in the inorganic insulating film 116A by etching the inorganic insulating film 116A in the pattern of the photosensitive organic film 116B, contact holes can be formed in the lower layer insulating film 112 by etching the lower layer insulating film 112 in the patterns of the inorganic insulating film 116A and the photosensitive organic film 116B. This eliminates the specialized photolithography steps (photomasks) to form contact holes at least in the lower layer insulating film 112 and the gate insulating film 114. Also, contact holes in the lower layer insulating film 112 can be formed without fail.

Furthermore, in the semiconductor layer resistance reduction step S4, the conduction imparted portions 113A are formed by the resistance reduction treatment on the semiconductor layer 113 using the gate insulating film 114 and the upper layer gate electrodes 103G2 as masks. Here, the gate insulating film 114 and the upper layer gate electrodes 103G2 can be patterned in the same step (upper layer gate electrode and gate insulating film formation step S3), and TFTs (double gate TFTs) in which gate electrodes are formed in the upper and lower layers of the channel region can be produced, whereby TFTs exhibiting stable performance in the on and off states.

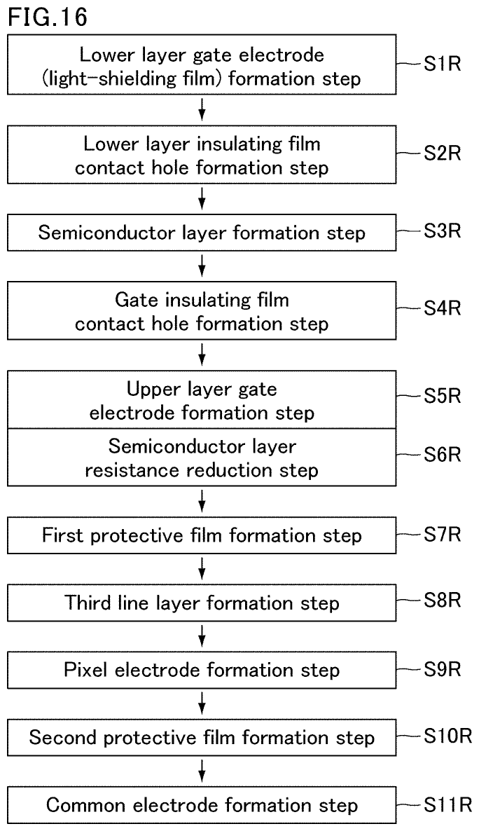

In contrast, the production process of the liquid crystal display device 1R of Comparative Embodiment 1 requires more steps than in the present embodiment. FIG. 16 is a view showing the production process of the TFT substrate in the liquid crystal display device of Comparative Embodiment 1. The production process of the liquid crystal display device 1R of Comparative Embodiment 1 is described with reference to FIG. 16.

A lower layer gate electrode (light-shielding film) formation step S1R is performed in the same manner as the lower layer gate electrode (light-shielding film) formation step S1 in Embodiment 1.

In a lower layer insulating film contact hole formation step S2R, the lower layer insulating film 112R is formed on the first conductive line layer 111R by chemical vapor deposition (CVD), and a resist pattern is formed by photolithography using a photomask. The lower layer insulating film 112R is patterned by etching using the resist pattern as a mask. The resist pattern is then removed, so that contact holes are formed in the lower layer insulating film 112.

In a semiconductor layer formation step S3R, a semiconductor film is formed on the lower layer insulating film 112R by sputtering, and a resist pattern is formed by photolithography using a photomask. The semiconductor film is patterned by etching using the resist pattern as a mask. The resist pattern is then removed, so that the semiconductor layer 113R is formed.

In a gate insulating film contact hole formation step S4R, the gate insulating film 114R is formed on the semiconductor layer 113R by CVD, and a resist pattern is formed by photolithography using a photomask. The gate insulating film 114R is patterned by etching using the resist pattern as a mask. The resist pattern is then removed, so that contact holes are formed in the gate insulating film 114R.

In an upper layer gate electrode formation step SSR, a second conductive film is formed on the gate insulating film 114R by sputtering, and a resist pattern is formed by photolithography using a photomask. The second conductive film is patterned by etching using the resist pattern as a mask, so that the second conductive line layer 115R including the upper layer gate electrodes 103G2R is formed. The gate insulating film 114R is patterned by etching also using the above resist pattern, followed by removal of the resist pattern. Here, the patterning of the gate insulating film 114R is not performed in one step but performed in the gate insulating film contact hole formation step S4R and the upper layer gate electrode formation step SSR. This is because by patterning the gate insulating film 114R in the gate insulating film contact hole formation step S4R, contact holes are formed in which the second conductive film (upper layer gate electrodes 103G2R) and the first conductive film (lower layer gate electrodes 103G1R) are to be directly connected to each other. Each contact hole 100CH1R in which the corresponding upper layer gate electrode 103G2R and the corresponding lower layer gate electrode 103G1R are directly connected to each other needs to be formed right below the upper layer gate electrode 103G2R. In the upper layer gate electrode formation step SSR, however, no contact hole can be formed in this portion (the portion right below the upper layer gate electrode 103G2R), and thus the contact holes 100CH1R need to be formed in advance in the gate insulating film contact hole formation step S4R.

In a semiconductor layer resistance reduction step S6R, the semiconductor layer 113R is subjected to the resistance reduction treatment using the upper layer gate electrodes 103G2R and the gate insulating film 114R overlapping the upper layer gate electrodes 103G2R as masks so as to form conduction imparted portions. In the gate insulating film contact hole formation step S4R, it is possible to remove the gate insulating film 114R in the portion overlapping the semiconductor layer 113R to be subjected to the resistance reduction treatment simultaneously with formation of contact holes in the gate insulating film 114R, and subject the semiconductor layer 113R to the resistance reduction treatment using the gate insulating film 114R as a mask. In this case, however, the TFTs do not have the self-alignment structure.

In the first protective film formation step S7R, the inorganic insulating film 116AR is formed on the second conductive line layer 115R by CVD. A photosensitive organic film material is applied to the inorganic insulating film 116AR by spin coating or slit coating, and the material is patterned by photolithography using a photomask, so that the photosensitive organic film 116BR is formed. The inorganic insulating film 116AR is etched in the pattern of the photosensitive organic film 116BR to form contact holes in the inorganic insulating film 116AR.

The third conductive line layer formation step S8R is performed in the same manner as the third conductive line layer formation step S6 in Embodiment 1.

The pixel electrode formation step S9R is performed in the same manner as the pixel electrode formation step S7 in Embodiment 1.

The second protective film formation step S10R is performed in the same manner as the second protective film formation step S8 in Embodiment 1.

The common electrode formation step S11R is performed in the same manner as the common electrode formation step S9 in Embodiment 1.

The production process of the liquid crystal display device of Comparative Embodiment 1 requires, as described for the lower layer insulating film contact hole formation step S2R, a specialized photolithography step (photomask) to form contact holes in the lower layer insulating film 112R. Also, the production step requires, as described for the gate insulating film contact hole formation step S4R, a specialized photolithography step (photomask) to form contact holes in the gate insulating film 114R.

### Embodiment 2

In the present embodiment, features unique to the present embodiment are mainly described, and the same features as those in the above embodiment are not described again. In Embodiment 1, each lower layer gate electrode and the corresponding upper layer gate electrode are connected to the switching electrode at one side of the semiconductor layer. In the present embodiment, the lower layer gate electrode and the upper layer gate electrode are connected to the switching electrode at both sides of the semiconductor layer.

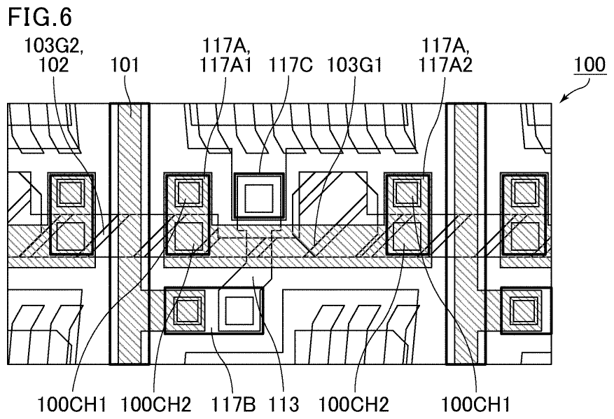

FIG. 6 is a schematic plan view of a liquid crystal display device of Embodiment 2. FIG. 6 shows the third conductive line layer 117 with thick lines. As shown in FIG. 6, each lower layer gate electrode 103G1 and the corresponding upper layer gate electrode 103G2 in the present embodiment are connected to each other via the switching electrode 117A at both sides of the semiconductor layer 113 (each channel width direction side of the semiconductor layer 113). This structure can reduce the resistance of the gate lines 102 and increase the redundancy of the gate lines 102.

Specifically, in the present embodiment, two switching electrodes 117A are formed for one lower layer gate electrode 103G1. Hereinafter, one of the switching electrodes 117A is referred to as a switching electrode 117A1 and the other is referred to as a switching electrode 117A2. Each lower layer gate electrode 103G1 and the corresponding upper layer gate electrode 103G2 are connected to each other via the corresponding switching electrode 117A1 at one side of the semiconductor layer 113, and the lower layer gate electrode 103G1 and the upper layer gate electrode 103G2 are connected to each other via the corresponding switching electrode 117A2 at the other side of the semiconductor layer 113.

The switching electrode 117A1 is connected to the lower layer gate electrode 103G1 in the corresponding contact hole 100CH1 in the first protective film 116 and the lower layer insulating film 112 and connected to the upper layer gate electrode 103G2 in the corresponding contact hole 100CH2 in the first protective film 116. Likewise, the switching electrode 117A2 is connected to the lower layer gate electrode 103G1 in the contact hole 100CH1 in the first protective film 116 and the lower layer insulating film 112 and connected to the upper layer gate electrode 103G2 in the contact hole 100CH2 in the first protective film 116.

### Embodiment 3

In the present embodiment, features unique to the present embodiment are mainly described, and the same features as those in the above embodiments are not described again. In Embodiments 1 and 2, the FFS mode liquid crystal display devices are described. In the present embodiment, liquid crystal display devices are described which are in modes in which pixel electrodes are disposed on the TFT substrate and the counter electrode is disposed on the counter substrate, i.e., the twisted nematic (TN) mode and the vertical alignment (VA) mode (4-domain reverse twisted nematic (4D-RTN) mode utilizing a photoalignment technique).

In the TN mode, the pixel electrodes 118 are disposed on the TFT substrate 100A, the common electrode 120 is disposed on the counter substrate 100B, and in the liquid crystal layer, liquid crystal molecules are aligned with the alignment of the liquid crystal molecules, rotating in one direction, being twisted by 90° from the pixel electrode 118 side to the common electrode 120 side.

In the VA mode, the pixel electrodes 118 are disposed on the TFT substrate 100A, the common electrode 120 is disposed on the counter substrate 100B, and negative liquid crystals are aligned perpendicular to the substrate surface in the liquid crystal layer with no voltage applied between the pixel electrodes 118 and the common electrode 120.

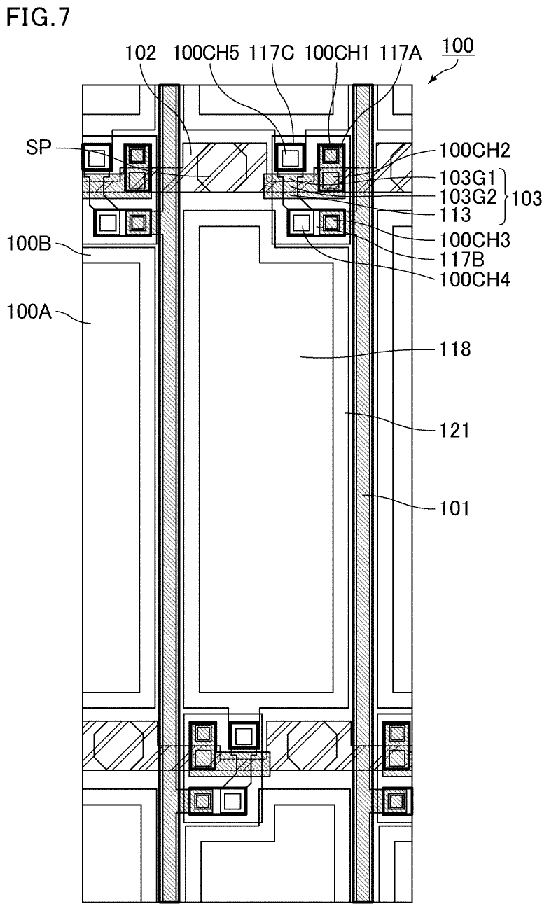

FIG. 7 is a schematic plan view of a liquid crystal display device of Embodiment 3. FIG. 7 shows the third conductive line layer 117 with thick lines. The structure of the TFTs 103 is the same as in Embodiment 1, but the positional relationship between the common electrode 120 and the pixel electrodes 118 is opposite from that in Embodiments 1 and 2; the common electrode 120 is disposed in the lower layer (on the insulating substrate 110 side) of the pixel electrodes 118. Also, a counter electrode that generates electric fields with the pixel electrodes 118 across the liquid crystal layer is formed on the counter substrate 100B and the common electrode 120 functions as an electrode to form auxiliary capacitance.

The counter electrode can be formed by, for example, forming a single-layer or multi-layer film of a transparent conductive material such as indium tin oxide (ITO), indium zinc oxide (IZO), zinc oxide (ZnO), or tin oxide (SnO) or an alloy thereof by a method such as sputtering, and then patterning the film by photolithography.

### Embodiment 4

In the present embodiment, features unique to the present embodiment are mainly described, and the same features as those in the above embodiments are not described again. In Embodiments 1 to 3, the liquid crystal display devices are described. In the present embodiment, an organic electroluminescent display device (hereinafter, also referred to as an organic EL display device or an organic light emitting diode (OLED) display) is described.

In the liquid crystal display devices of Embodiments 1 to 3, the insulating substrate in the array substrate functioning as the TFT substrate is a rigid substrate such as a glass substrate. The present embodiment relates to a top-emission organic EL display device whose backplane substrate corresponding to the array substrate is a flexible substrate containing a material such as a polyimide.

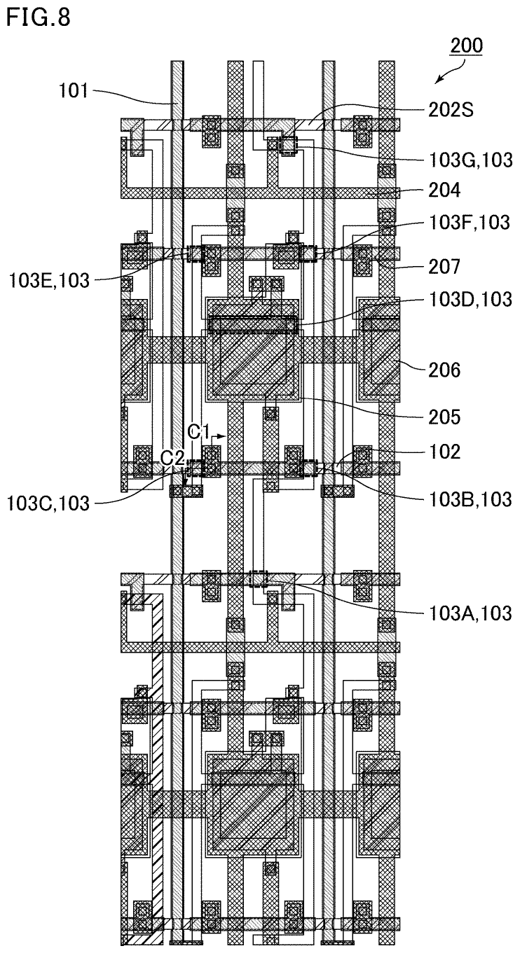

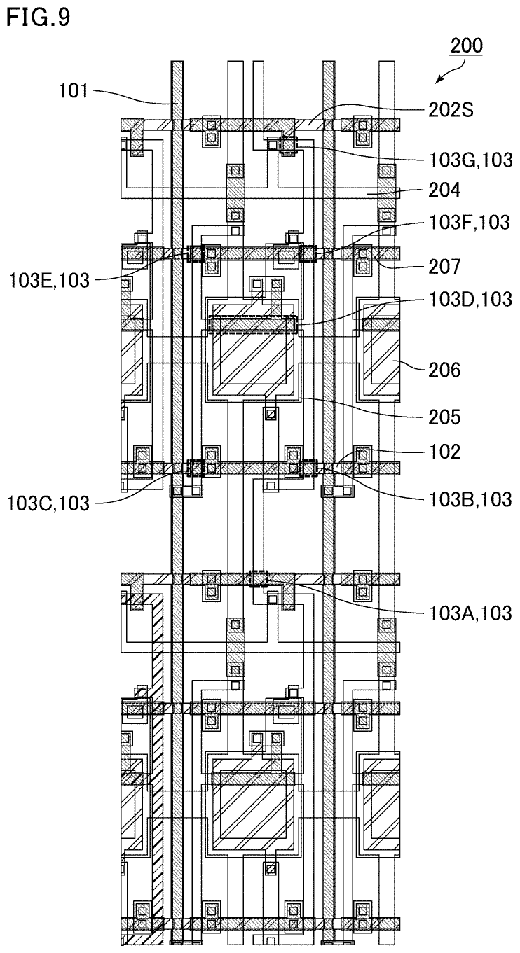

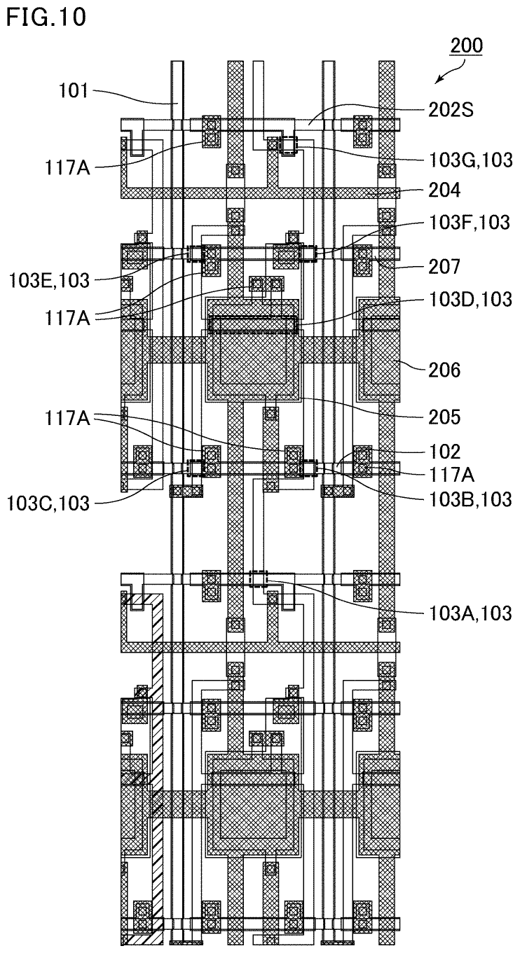

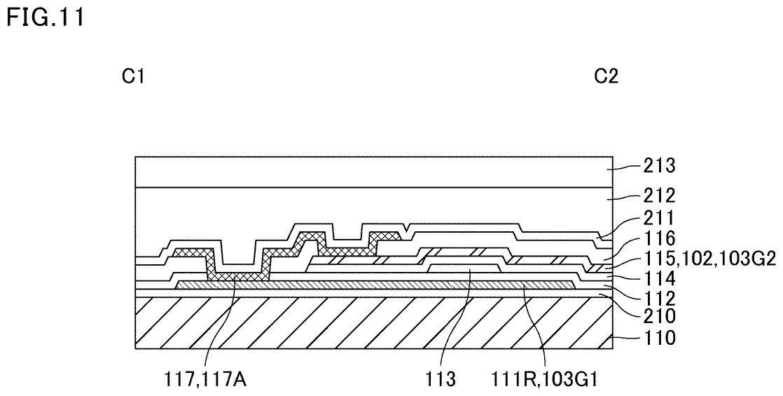

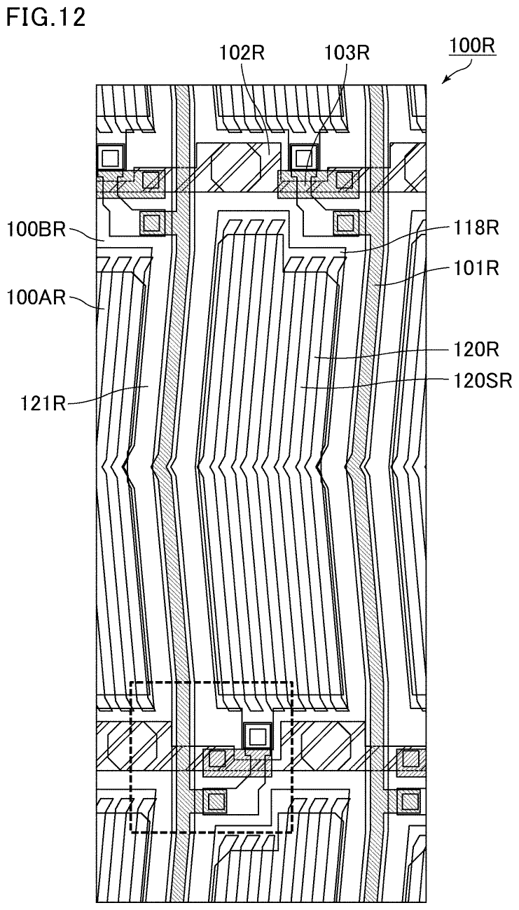

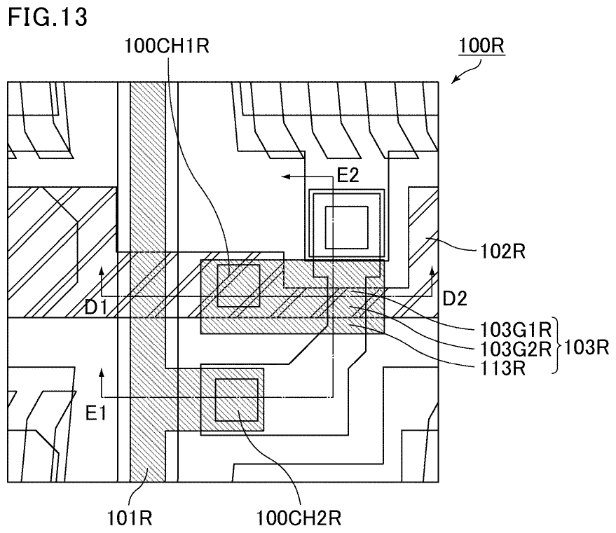

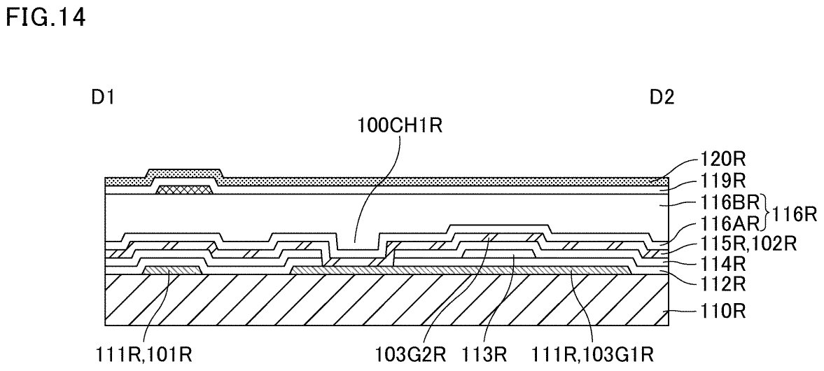

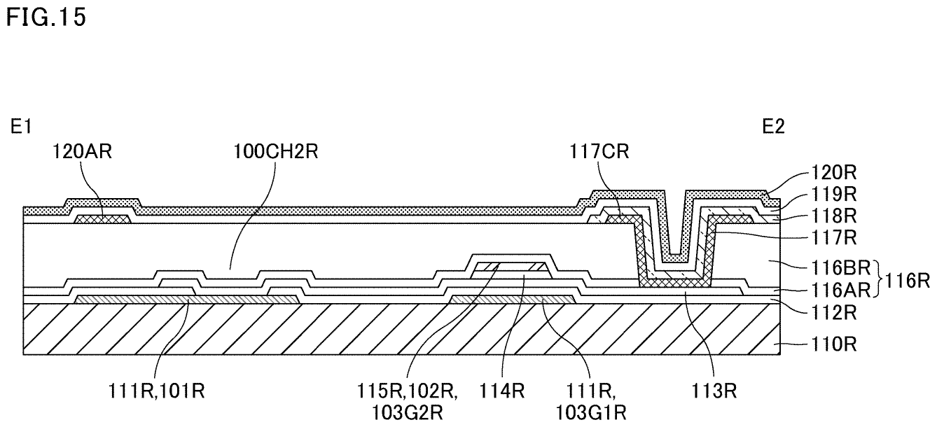

FIG. 8 is a schematic plan view of the organic electroluminescent display device of Embodiment 4. FIG. 9 is a schematic plan view of the organic electroluminescent display device of Embodiment 4, with a first conductive line layer and a second conductive line layer highlighted. FIG. 10 is a schematic plan view of the organic electroluminescent display device of Embodiment 4, with a third conductive line layer highlighted. FIG. 11 is a schematic cross-sectional view of the organic electroluminescent display device of Embodiment 4. FIGS. 8 and 10 show the third conductive line layer 117 with grid-like hatching. FIG. 11 shows the cross section taken along the line C1-C2 in FIG. 8.

As shown in FIGS. 8 to 10, each pixel in an organic EL display device (OLED display) 200 includes switching elements (seven TFTs 103A to 103G in FIG. 8). Here, each of the TFTs 103A to 103G is also referred to as a TFT 103. As in the above embodiments, each TFT 103 in the present embodiment includes, as shown in FIG. 11, a lower layer gate electrode 103G1 in the first conductive line layer 111, an upper layer gate electrode 103G2 in the second conductive line layer 115, and a switching electrode 117A in the third conductive line layer 117 on the third insulating film 116. The lower layer gate electrode 103G1 and the upper layer gate electrode 103G2 are connected to each other via the switching electrode 117A. Thus, contact holes can be formed in the first insulating film 112 using the photomask used to pattern the third insulating film 116. In other words, no specialized photomask to form contact holes in the first insulating film 112 is necessary, which enables reduction in the number of photomasks used in the production process.

As shown in FIGS. 8 to 10, each pixel in the organic EL display device 200 may include, as well as the gate lines 102, a signal line (sub gate line 202S) to which the same signal as the signal input to a gate line 102 in another row.

For example, to the sub gate line 202S is supplied the same signal as the signal supplied to the gate line 102 in the previous pixel row. This sub gate line 202S is a signal line that controls the TFT 103A provided to initialize the gate electrode potential of the TFT 103D to a given potential (potential of an initialization power line 204). The TFT 103D is an element that controls the amount of current to be supplied to an OLED device layer, and one of its source electrode and drain electrode is connected, via the TFT 103F, to a reflective electrode (anode side electrode) 205. In an upper layer relative to the reflective electrode 205 is formed the OLED device layer by deposition. To the other electrode is connected the corresponding data line 101 via the TFT 103C and also connected, via the TFT 103E, a power line (anode side power line 206) that supplies power to the OLED device layer.

In the present embodiment, as shown in FIG. 11, a basecoat film 210 is formed in a further lower layer of the lower layer gate electrodes 103G1 (between the lower layer gate electrodes 103G1 and the insulating substrate 110), and the first protective film 116 may not include a photosensitive organic film. In the upper layer of the third conductive line layer 117 are disposed pixel electrodes formed from a highly reflective metal material such as silver via an inorganic film 211 and a flattering film 212. In the upper layer of the pixel electrodes is formed a protective layer 213.

The TFT 103 in the present embodiment can be applied not only to the TFT 103F connected to the corresponding pixel electrode 118 but also to each of the TFTs 103A to 103G having various functions.

In the present embodiment, the third conductive line layer 117 is usable as the initialization power line 204 or the anode side power line 206. The second conductive line layer constituting the gate lines 102 and the upper layer gate electrodes 103G2 also constitutes em lines 207 parallel to the gate lines 102. To the em lines 207 is supplied a signal for controlling the TFTs 103E and 103F that switch between the light emission period and the no light emission period of the OLED device layer (grayscale data writing period). As described above, application of the concept of the present embodiment is not limited to the TFTs 103 connected to the pixel electrodes 118 in the liquid crystal display device 100.

What is claimed is:

1. A thin-film transistor substrate comprising:
an insulating substrate; and
a thin-film transistor disposed on the insulating substrate,
the thin-film transistor substrate including, on the insulating substrate, a stack sequentially including a first conductive line layer, a first insulating film, a semiconductor layer, a second insulating film, a second conductive line layer, a third insulating film, and a third conductive line layer,
the thin-film transistor including a lower layer gate electrode in the first conductive line layer, the semiconductor layer, an upper layer gate electrode in the second conductive line layer, and a switching electrode in the third conductive line layer,
the lower layer gate electrode and the upper layer gate electrode being connected to each other via the switching electrode.

2. The thin-film transistor substrate according to claim 1,
wherein the lower layer gate electrode and the upper layer gate electrode are connected to each other via the switching electrode at both sides of the semiconductor layer.

3. The thin-film transistor substrate according to claim 1,
wherein the switching electrode includes a first switching electrode and a second switching electrode,
the lower layer gate electrode and the upper layer gate electrode are connected to each other via the first switching electrode at one side of the semiconductor layer, and
the lower layer gate electrode and the upper layer gate electrode are connected to each other via the second switching electrode at the other side of the semiconductor layer.

4. The thin-film transistor substrate according to claim 1, further comprising at least one of a conductive line or an electrode in the third conductive line layer.

5. A liquid crystal display device comprising the thin-film transistor substrate according to claim 1.

6. An organic electroluminescent display device comprising the thin-film transistor substrate according to claim 1.
